(19) United States
(12) Patent Application Publication
(10) Pub. No.: US 2026/0046986 A1
(43) Pub. Date: Feb. 12, 2026

(54) SOLID-STATE RF POWER GENERATION AND CONTROL FOR DIELECTRIC HEATING

(71) Applicant: Aethera Technologies Limited, Halifax (CA)

(72) Inventors: Brian Walker, Halifax (CA); Kirk Zwicker, Halifax (CA); Charles Schue, N. Billerica, MA (US); Aaron DeBaie, Halifax (CA); Arjun Warrier, Halifax (CA)

(73) Assignee: Aethera Technologies Limited, Halifax (CA)

(21) Appl. No.: 19/296,517

(22) Filed: Aug. 11, 2025

Related U.S. Application Data
(60) Provisional application No. 63/681,626, filed on Aug. 9, 2024.

(51) Int. Cl. H05B 6/50; H03F 3/24

(52) U.S. Cl. CPC H05B 6/50; H03F 3/245; H03F 2200/451

(57) ABSTRACT

A radio frequency (RF) dielectric heating system includes a solid-state RF power generator, a matching network electrically coupled to the RF power generator, and a dielectric heating applicator electrically coupled to the matching network and including electrodes for applying RF power to a dielectric material. A solid-state RF power generator can include a power supply, an RF power amplifier stage electrically coupled to the power supply, and a control system electrically coupled to and configured to control the RF power amplifier stage. The control system can be configured to regulate an output voltage of the RF power generator to provide a constant RF power generator output current to maintain a constant voltage across the applicator electrodes. Examples of RF power generators and methods for RF dielectric heating are also disclosed.

### CROSS-REFERENCE TO RELATED APPLICATIONS

This application claims priority to U.S. Provisional Application No. 63/681,626 filed Aug. 9, 2024, and entitled “Solid-State RF Power Generation and Control for Dielectric Heating,” which is hereby incorporated by reference in its entirety under 35 U.S.C. § 119 (e).

### TECHNICAL FIELD

The disclosed technology relates to devices, systems, and methods for dielectric heating with radio frequency (RF) power, and more particularly relates to controlling solid-state RF power generators to provide dielectric heating.

### BACKGROUND

Dielectric heating is the process of heating a dielectric material with RF power. Dielectric heating has been used in a variety of industrial processes including, for example, heating, drying, and tempering various materials. A typical dielectric heating system includes an RF power generator connected to what is generally known as an applicator. The applicator is designed to safely apply the RF power to the targeted material through the use of electrodes. In one common configuration, the material being heated is positioned between two parallel conductive plates acting as the electrodes. To provide an efficient transfer of power from the RF generator to the electrodes, and subsequently to the load, a matching network is typically connected between the RF generator and the applicator.

Vacuum tube-based RF power generators have traditionally been employed for industrial RF heating applications. However, semiconductor-based solid-state RF power generators are now increasingly being used for these applications. Solid-state RF power generators use transistor technology to generate RF fields, in contrast to the vacuum tubes used in legacy systems. Such technology enables precise control of the frequency and power delivered to the material being processed. Solid-state RF applications thus benefit from very agile control of the created electromagnetic fields, typically with microsecond scale control of frequency, phase, and power level.

In a typical configuration, an RF power generator is a high-frequency energy source that creates an electric field across a pair of electrode plates forming part of the applicator. Heat is generated in the dielectric material positioned between the electrodes from electrical losses that occur due to the non-conductive nature of the material. Accordingly, materials such as rubber, plastics, and wood effectively form a lossy capacitor linked to a radio frequency oscillator when positioned between the electrodes. In the case of a homogeneous material, the generated heat tends to distribute evenly throughout the material, heating the material from within.

In various industrial processes, uniform heating throughout the material can be achieved with a constant voltage across the electrodes of the applicator. The voltage level is subject to change, though, due to changes in the target material, which effectively forms the load portion of the RF circuit. Accordingly, there is a need in the art for devices, systems, and methods for maintaining a constant voltage across the applicator electrodes despite changes to the material load positioned between the electrodes.

### SUMMARY

The disclosed technology provides implementations of systems, devices, and methods related to solid-state RF power generation for dielectric heating.

According to one aspect of the disclosed technology, an RF dielectric heating system includes a solid-state RF power generator, a matching network electrically coupled to the RF power generator, and a dielectric heating applicator electrically coupled to the matching network. The solid-state RF power generator has a power supply, an RF power amplifier stage electrically coupled to the power supply, and a control system electrically coupled to and configured to control the RF power amplifier stage. The dielectric heating applicator includes electrodes for applying RF power to a dielectric material. The control system is configured to regulate an output voltage of the RF power generator to provide a constant RF power generator output current to maintain a constant voltage across the applicator electrodes.

Implementations according to this aspect of the disclosure may include one or more of the following features. In some cases the RF power amplifier stage includes a single RF power amplifier. In some cases the RF power amplifier stage includes a plurality of RF power amplifiers, and the RF power generator further includes a combiner configured to combine outputs from the plurality of RF power amplifiers to produce an output RF signal. In some cases the RF power generator is configured to regulate the output voltage of the RF power generator through pulse width modulation (PWM). In various implementations, the PWM includes modulating a supply voltage of the amplifier stage. In various cases the control system is configured to generate an amplifier control signal to operate the RF power amplifier stage. In such cases the PWM can include regulating the output voltage of the RF power generator by modulating the amplifier control signal.

Additional possible features include the control system being configured to regulate the output voltage of the RF power generator through pulse code modulation (PCM). In some cases the control system is configured to regulate the output voltage of the RF power generator through sigma-delta modulation. In various cases the RF dielectric heating system includes an unbalanced topology wherein the RF power generator is the only RF power generator. In some cases the heating system includes a balanced topology wherein the RF power generator is the only RF power generator. In various implementations the RF power generator is a first RF power generator and the matching network is a first matching network, and the system further includes a second RF power generator and a second matching network electrically coupled between the second RF power generator and the dielectric heating applicator, wherein a control system of the second RF power generator is configured to drive the second RF power generator 180 degrees out of phase with the first RF power generator.

According to another aspect of the disclosed technology, a solid-state RF power generator for a dielectric heating system has an RF generator output for electrically coupling to a matching network of a dielectric heating system, an RF power amplifier stage electrically coupled to the RF generator output and including one or more RF power amplifiers, a power supply electrically coupled to the RF power amplifier stage, and a control system electrically coupled to the RF power amplifier stage. The control system is configured to regulate an output voltage at the RF generator output to provide a constant output current at the RF power generator output for driving a dielectric heating applicator of the dielectric heating system with a constant voltage.

Implementations according to this aspect of the disclosure may include one or more of the following features. In some cases the power generator further includes a combiner electrically coupled between the RF power amplifier stage and the RF generator output. The RF power amplifier stage includes a plurality of RF power amplifiers, and the combiner is configured to combine outputs from the plurality of RF power amplifiers to produce the output voltage at the RF generator output. In various cases the power generator includes a PWM circuit configured to regulate the output voltage. In various cases the PWM circuit is configured to regulate the output voltage by modulating a supply voltage generated by the power supply for the amplifier stage. In some cases the control system is configured to generate an amplifier control signal to operate the RF power amplifier stage and the PWM circuit is configured to regulate the output voltage by modulating the amplifier control signal. In various cases the control system is configured to regulate the output voltage with PCM. In various cases the control system is configured to regulate the output voltage with sigma-delta modulation.

Another aspect of the disclosed technology relates to a method for heating a dielectric material with an RF dielectric heating system. The method includes maintaining a constant voltage across electrodes of a dielectric heating applicator and applying a constant current to a matching network electrically coupled to the dielectric heating applicator to generate the constant voltage. The method also includes regulating an output voltage of an RF power generator to provide the constant current.

Implementations according to this aspect of the disclosure may include one or more of the following features. In various cases the method further includes using pulse width modulation to regulate the output voltage. In various cases the method further includes using pulse code modulation to regulate the output voltage. In various cases the method further includes using sigma-delta modulation to regulate the output voltage. In various cases the method further includes maintaining the constant voltage with an unbalanced topology comprising a single RF power generator. Various implementations further include maintaining the constant voltage with a balanced topology comprising a single RF power generator. In various cases the method further includes maintaining the constant voltage with a balanced topology comprising a first RF power generator and a second RF power generator.

Another aspect of the disclosed technology provides a method for heating a dielectric material with an RF dielectric heating system that includes maintaining a constant voltage across electrodes of a dielectric heating applicator, optionally with a balanced or an unbalanced topology comprising one or more RF power generators. The method further includes applying a constant current to a matching network electrically coupled to the dielectric heating applicator to generate the constant voltage and regulating an output voltage of an RF power generator. In various cases the method includes providing the constant current through regulating the output voltage of the RF power generator with one or more of pulse width modulation, pulse code modulation, and sigma-delta modulation.

In Example 1, a radio frequency (RF) dielectric heating system comprising a solid-state RF power generator including a power supply, an RF power amplifier stage electrically coupled to the power supply, and a control system electrically coupled to and configured to control the RF power amplifier stage, a matching network electrically coupled to the RF power generator, and a dielectric heating applicator electrically coupled to the matching network and comprising electrodes for applying RF power to a dielectric material, wherein the control system is configured to regulate an output voltage of the RF power generator to provide a constant RF power generator output current to maintain a constant voltage across the applicator electrodes.

In Example 2, the RF dielectric heating system of Example 1, wherein the RF power amplifier stage comprises a single RF power amplifier.

In Example 3, the RF dielectric heating system of Example 1, wherein the RF power amplifier stage comprises a plurality of RF power amplifiers and the RF power generator further comprises a combiner configured to combine outputs from the plurality of RF power amplifiers to produce an output RF signal.

In Example 4, the RF dielectric heating system of any of Examples 1-3, wherein the control system is configured to regulate the output voltage of the RF power generator through pulse width modulation (PWM).

In Example 5, the RF dielectric heating system of Example 4, wherein the PWM comprises modulating a supply voltage of the amplifier stage.

In Example 6, the RF dielectric heating system of Example 4, wherein the control system is configured to generate an amplifier control signal to operate the RF power amplifier stage and the PWM comprises regulating the output voltage of the RF power generator by modulating the amplifier control signal.

In Example 7, the RF dielectric heating system of any of Examples 1-6, wherein the control system is configured to regulate the output voltage of the RF power generator through pulse code modulation (PCM).

In Example 8, the RF dielectric heating system of any of Examples 1-6, wherein the control system is configured to regulate the output voltage of the RF power generator through sigma-delta modulation.

In Example 9, the RF dielectric heating system of any of Examples 1-8, further comprising an unbalanced topology wherein the RF power generator is the only RF power generator.

In Example 10, the RF dielectric heating system of any of Examples 1-8, further comprising a balanced topology wherein the RF power generator is the only RF power generator.

In Example 11, the RF dielectric heating system of any of Examples 1-8, wherein the RF power generator is a first RF power generator and the matching network is a first matching network, and further comprising a second RF power generator and a second matching network electrically coupled between the second RF power generator and the dielectric heating applicator, wherein a control system of the second RF power generator is configured to drive the second RF power generator 180 degrees out of phase with the first RF power generator.

In Example 12, a solid-state radio frequency (RF) power generator for a dielectric heating system, the RF power generator comprising an RF generator output for electrically coupling to a matching network of a dielectric heating system, an RF power amplifier stage electrically coupled to the RF generator output and comprising one or more RF power amplifiers, a power supply electrically coupled to the RF power amplifier stage, and a control system electrically coupled to the RF power amplifier stage, wherein the control system is configured to regulate an output voltage at the RF generator output to provide a constant output current at the RF power generator output for driving a dielectric heating applicator of the dielectric heating system with a constant voltage.

In Example 13, the RF power generator of Example 12, further comprising a combiner electrically coupled between the RF power amplifier stage and the RF generator output, wherein the RF power amplifier stage comprises a plurality of RF power amplifiers and the combiner is configured to combine outputs from the plurality of RF power amplifiers to produce the output voltage at the RF generator output.

In Example 14, the RF power generator of Example 12 or Example 13, further comprising a pulse width modulation (PWM) circuit configured to regulate the output voltage.

In Example 15, the RF power generator of Example 14, wherein the PWM circuit is configured to regulate the output voltage by modulating a supply voltage generated by the power supply for the amplifier stage.

In Example 16, the RF dielectric heating system of Example 14, wherein the control system is configured to generate an amplifier control signal to operate the RF power amplifier stage and the PWM circuit is configured to regulate the output voltage by modulating the amplifier control signal.

In Example 17, the RF dielectric heating system of any of Examples 12-16, wherein the control system is configured to regulate the output voltage with pulse code modulation (PCM).

In Example 18, the RF dielectric heating system of any of Examples 12-16, wherein the control system is configured to regulate the output voltage with sigma-delta modulation.

In Example 19, a method for heating a dielectric material with an RF dielectric heating system comprising maintaining a constant voltage across electrodes of a dielectric heating applicator, applying a constant current to a matching network electrically coupled to the dielectric heating applicator to generate the constant voltage, and regulating an output voltage of an RF power generator to provide the constant current.

In Example 20, the method of Example 19, further comprising using pulse width modulation to regulate the output voltage.

In Example 21, the method of Example 19, further comprising using pulse code modulation to regulate the output voltage.

In Example 22, the method of Example 19, further comprising using sigma-delta modulation to regulate the output voltage.

In Example 23, the method of any of Examples 19-22, further comprising maintaining the constant voltage with an unbalanced topology comprising a single RF power generator.

In Example 24, the method of any of Examples 19-22, further comprising maintaining the constant voltage with a balanced topology comprising a single RF power generator.

In Example 25, the method of any of Examples 19-22, further comprising maintaining the constant voltage with a balanced topology comprising a first RF power generator and a second RF power generator.

In Example 26, a method for heating a dielectric material with an RF dielectric heating system comprising maintaining a constant voltage across electrodes of a dielectric heating applicator, optionally with a balanced or an unbalanced topology comprising one or more RF power generators, applying a constant current to a matching network electrically coupled to the dielectric heating applicator to generate the constant voltage, and regulating an output voltage of an RF power generator, optionally with one or more of pulse width modulation, pulse code modulation, and sigma-delta modulation, to provide the constant current.

While multiple implementations and aspects are disclosed, still other embodiments of the disclosure will become apparent to those skilled in the art from the following detailed description, which shows and describes illustrative embodiments of the disclosed apparatus, systems, and methods. As will be realized, the disclosed apparatus, systems and methods are capable of modifications in various obvious aspects, all without departing from the spirit and scope of the disclosure. Accordingly, the drawings and detailed description are to be regarded as illustrative in nature and not restrictive.

### BRIEF DESCRIPTION OF THE DRAWINGS

FIG. 1 is a simplified schematic representation of a dielectric heating system according to various implementations.

FIG. 2 is a representative equivalent parallel circuit depicting the complex impedance of a dielectric material according to various implementations.

FIG. 3 is a phasor diagram depicting currents flowing through a dielectric material according to various implementations.

FIG. 4 is a block diagram of a solid-state dielectric heating system according to various implementations.

FIG. 5 is a high-level schematic of a topology for the RF heating system according to various implementations.

FIG. 6 is a high-level schematic of a topology for the RF heating system according to various implementations.

FIG. 7 is a high-level schematic of a topology for the RF heating system according to various implementations.

FIG. 8 is a partial block diagram of an RF power generator according to various implementations.

FIG. 9 is a partial block diagram of an RF power generator according to various implementations.

FIG. 10 is a block diagram of a control system for an RF power generator according to various implementations.

FIG. 11 is a block diagram of a control system for an RF power generator according to various implementations.

### DETAILED DESCRIPTION

Aspects of the disclosed technology relate to RF power generators and the use of RF power in various applications. Dielectric heating is an example of an application that employs RF power. Various aspects and implementations of the technology are directed to and referred to broadly as, among other things, a dielectric heating system 100 and heating applicator 108, a method for heating dielectric materials with RF power, an RF power generator 110, and a control system 400 and method for controlling RF power generation, though it is understood that this is for brevity and is in no way intended to be limiting to any specific modality.

According to one aspect, various topologies for a solid-state RF dielectric heating system 100 provide dielectric heating by maintaining a constant voltage at the electrodes of an RF heating applicator 108. In various cases an RF power generator 110 can include a single RF power amplifier or multiple RF power amplifiers combined to achieve higher power levels.

Another aspect of the technology includes configuring the RF power generator 110 to provide the constant voltage at the applicator electrodes under varying applicator loads by generating a constant current output for driving a matching network and the applicator 108.

Another aspect of the technology provides various control methods for regulating the output voltage of the RF power generator 110 to achieve the constant current target. The RF generator acts as a voltage source and is controlled and switched to achieve the constant current output. According to various implementations, one or more types of control methods are used to supply the constant current output.

According to various implementations, RF power can be effectively used for generating heat in various industrial processes, including, but not limited to, heating, drying, tempering, pasteurizing, sanitizing, curing impregnating materials, disinfecting, gluing, and bonding. Implementations of the disclosed technology include examples described herein with respect to one or more specific applications, along with other compatible applications and contexts to which the teachings of the disclosure may likewise be applied.

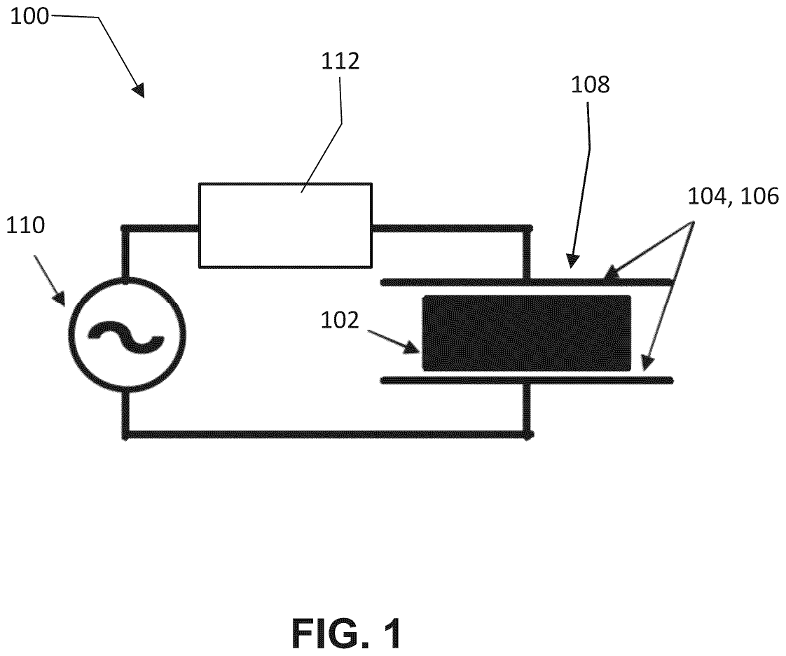

FIG. 1 is a simplified schematic representation of the dielectric heating system 100 according to various implementations. The heating system 100 depicts a targeted dielectric material 102 positioned between opposing electrode plates 104, 106 of a heating applicator 108, which is electrically connected to an RF power generator 110. There may be other components included within the heating system 100 and the applicator 108 such as insulators for mechanical support and components to assist with tuning the RF circuit, as well as components related to automation and material handling. Further, while one typical parallel plate electrode arrangement of a dielectric heating system is depicted and described herein, it is understood that there are other arrangements of electrodes and structures that achieve the equivalent functionality.

In a typical process of this nature, the RF power generator 110 produces power at an RF frequency and this power is transmitted through the circuit to the electrodes 104, 106. A matching network 112 is used to provide an efficient transfer of power from the RF generator 110 to the electrodes 104, 106.

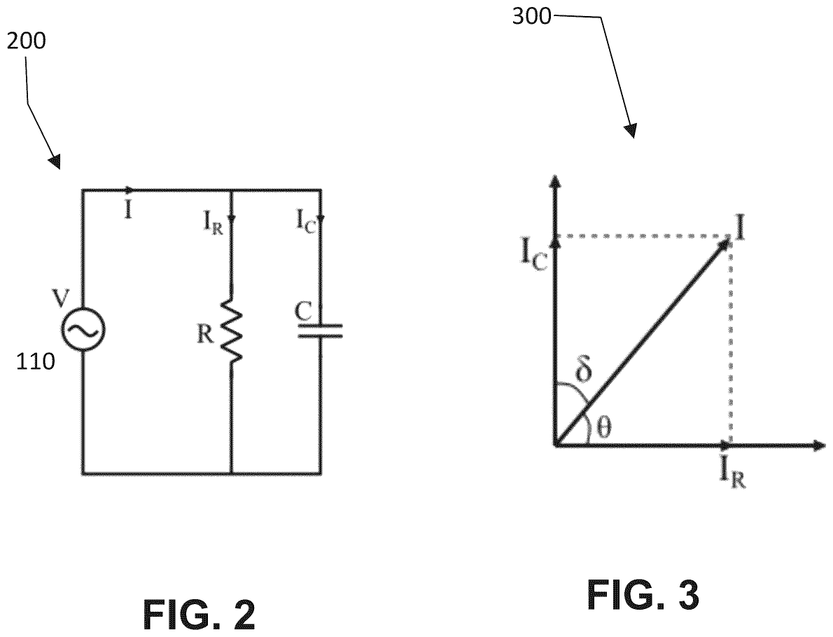

FIG. 2 is a representative equivalent parallel circuit 200 depicting the complex impedance presented to the RF power generator 110 by the dielectric material 102. FIG. 3 is a phasor diagram depicting the capacitive (I_{C}), resistive (I_{R}) and total current (I) flowing through the dielectric material 102 according to various implementations.

Generally speaking, the dielectric loss of a material partly governs the ability to heat the material. The loss is defined as the tangent of the loss angle δ shown in FIG. 3. Multiple factors can determine the amount of heat generated in a material, including the voltage (V) and the frequency (f) of the signal and properties of the material, including the dimensions, the dielectric loss factor (δ), and the relative permittivity (εr).

The power delivered per unit volume of the material can be shown as

$$P = 2 * π * f * ε 0 * ε r * {V}^{2} * tan ( δ )$$

in which ε0 is the permittivity of free space. The impedance of a parallel LC circuit is given by

$$Xp = j * ω * L / ( 1 - {ω}^{2} * L * C )$$

in which

$$j = \sqrt{- 1} ,$$

ω is the angular frequency,
L is the inductance, and
C is the capacitance.

In various cases the heating applicator can be modelled as a parallel resistor-capacitor (RC) circuit. Optionally, the equivalent impedance of the applicator can be further increased by adding parallel inductance in the form of one or more stubs. Various implementations of a dielectric heating applicator include the equivalent circuit and the variations thereof, such as additional stubs.

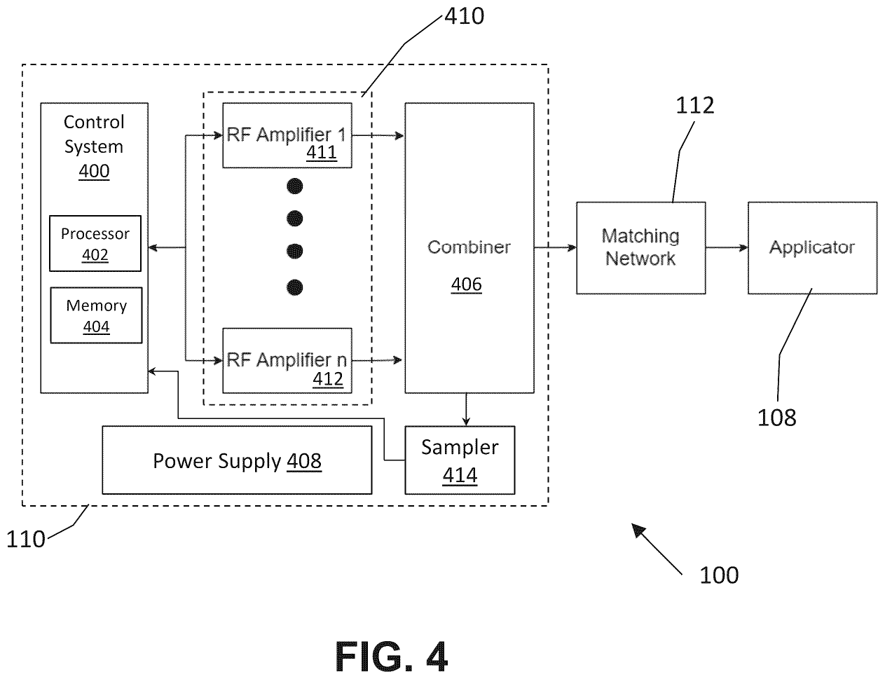

Implementations of the disclosed technology include RF power generators and/or solid-state dielectric heating systems that employ semiconductor-based, solid-state components (e.g., transistors) instead of vacuum tubes to convert DC voltage into an RF signal. FIG. 4 is a block diagram of a solid-state dielectric heating system 100 according to various implementations. The heating system 100 in this example includes an RF power generator 110 electrically coupled to an applicator 108 through a matching network 112.

The RF power generator 110 includes an RF power amplifier stage 410 made up of one or more RF power amplifiers 411, 412. The output(s) of the one or more RF power amplifiers are combined in a power combiner 406 configured to combine each individual RF signal from the RF power amplifier stage 410 to produce an output RF signal (e.g., RF voltage and current) of suitable magnitude to be delivered to the applicator 108 via the matching network 112. The RF power generator 110 further includes a control system 400 configured to operate various aspects of the RF power generator 110. A power supply 408 provides operating power as well as an input voltage for the amplifier stage 410. In various cases the power supply 408 is configured to convert an AC input voltage (e.g., from an AC utility mains) to a DC voltage.

In various implementations the RF power generator 110 includes one or more feedback loops that enable the control system 400 to monitor the output of the power combiner 406. For example, FIG. 4 illustrates that in various implementations the power generator 110 includes a sampler 414 configured to sample the output of the power combiner 406 and generate and relay a corresponding feedback signal to the control system 400. Although shown separately in FIG. 4, it is contemplated that the sampler 412 can also be provided as part of the control system 400.

The solid-state RF power amplifier(s) making up the amplification stage 410 include transistors such as, for example, IGBTs (Insulated Gate Bipolar Transistors) or MOSFETs (Metal Oxide Field Effect Transistors). The transistors are arranged in a manner that allows switching of the DC voltage at a high rate to produce RF energy at its output.

In various implementations the control system 400 is configured to generate switching waveforms to control the RF power amplifiers making up the amplifier stage 410, the properties of which are dynamically adjusted to optimize the power generated and, in turn, delivered to the load placed at the applicator 108. In various cases the control system 400 includes a computer processor 402 or processing circuitry configured to control the RF power amplifiers in a particular manner. In some cases, the processor is a microcontroller, or a microprocessor configured or programmed with instructions residing in a computer memory device 404 (e.g., integral or separate RAM).

Various implementations of the disclosed technology include an RF power generator configured to maintain a constant voltage across the electrodes of a dielectric heating applicator to produce uniform heating throughout the dielectric material. For example, the RF power generator is configured in various implementations to provide a particular voltage within an acceptable tolerance, as will be understood by those skilled in the art. It will be further understood that various voltage and tolerance levels may be used depending on, for example, the specific dielectric material and/or other factors associated with a particular implementation of the disclosed technology. In various implementations the control system 400 further addresses a need for flexibility in configuring the output power delivered to the material.

In the current state-of-the-art, solid-state RF generators typically have a lower output voltage at a higher current than an equivalent vacuum tube generator. Due to a low equivalent series resistance and inductance, solid-state RF generators can approximate the performance of an ideal voltage source. Even so, solid-state RF power generators are typically unable to directly drive a dielectric heating applicator without developing additional voltage.

According to various implementations of the disclosed technology, voltage magnification using series configured resistive, inductive, and capacitive (RLC) elements with a high-quality factor (Q) (e.g., typically on the order of 50-100) are used to develop additional voltage at the applicator. In various implementations a dielectric heating system includes a matching network with reactive components that can maximize the amount of RF power transferred from the power amplifiers to the load placed at the applicator.

### System Topologies

Implementations of the disclosed technology may employ one of multiple heating system topologies that maintain a constant voltage at the electrodes of an RF heating applicator. In the examples discussed herein, the large reactance of a capacitor and an inductor in comparison to the resistance of the heating applicator effectively transforms a constant current from the RF power generator into a constant voltage across the applicator electrodes. A constant electrode voltage is preferable for many heating applications because the constant electrode voltage will result in uniform heating throughout the industrial process.

Although various topologies have been illustrated using the disclosed examples, those skilled in the art will recognize that there exist numerous alternative arrangements and adaptations of the disclosed systems and topologies. Additional embodiments may be employed, and adjustments in structure and functionality can be implemented, without deviating from the scope of the disclosure. As a simple example, in any of these systems an RF power generator can include a single RF power amplifier, or multiple RF power amplifiers combined to achieve higher power levels.

Topology 1: Unbalanced Operation from a Single RF Generator

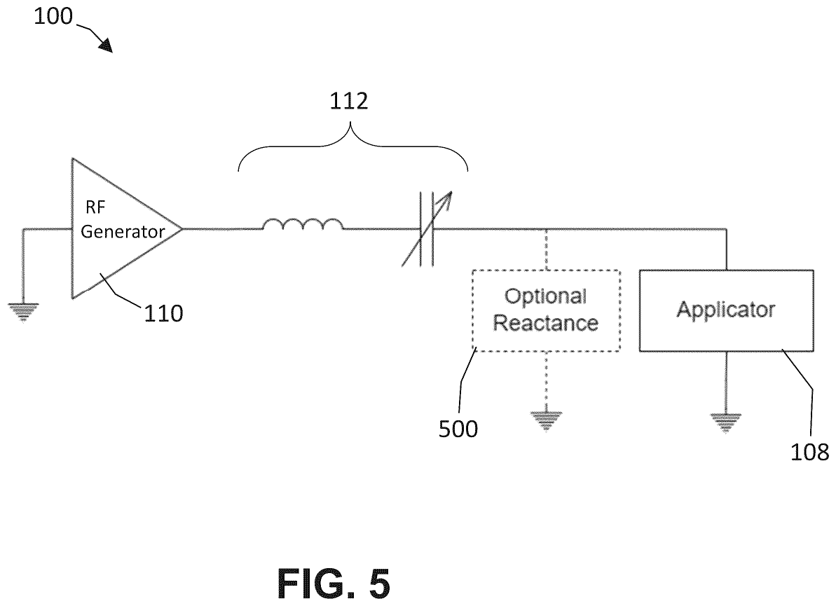

FIG. 5 is a high-level schematic of one possible topology for the RF heating system 100 according to various implementations. The heating system 100 in this example includes an unbalanced RF power generator 110, a matching network 112, and a heating applicator 108. The RF power generator drives a constant RF current through the series reactance in the matching network 112, thereby producing the desired voltage between the applicator's hot and grounded electrode plates (not shown). The high Q of the series RLC circuit transforms the constant current from the generator 110 to a constant voltage of much higher magnitude across the electrodes of the applicator 108.

The topology implementation of FIG. 5 has the benefit of a simple setup and installation when compared with other topologies. On the other hand, the applicator electrodes can have parasitic paths to ground. In the unbalanced system, the grounded electrode can effectively be partially shorted out by these parasitic paths, resulting in non-uniform distribution of the electric field lines within the material. This, in turn, could result in non-uniform heating of the dielectric material.

While a simple embodiment of the topology is shown below, variations of the topology, including optional shunt elements 500, can also be implemented. Further, in some cases the shunt reactive elements 500 can be located anywhere in the signal chain from the output of the power generator 110 to the applicator 108.

Topology 2: Balanced Operation from a Single RF Power Generator

In applications where corona discharges and arcing concerns exist, it can be beneficial to drive the heating applicator 108 using a balanced RF source. In such cases, each applicator electrode is driven differentially at the same potential with respect to ground.

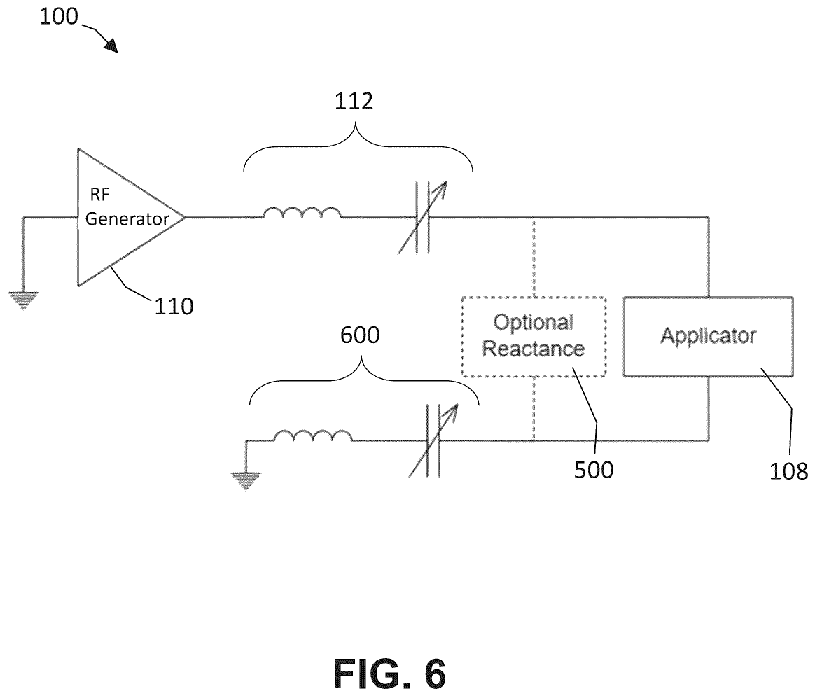

As shown in the high-level schematic of FIG. 6, in this topology the series reactance 600 in the grounded leg sets the voltage from the lower electrode to system ground. Because the parasitic paths to system ground are similar on both sides of the applicator 108 in the balanced topology, the electric field lines extending between electrodes are more uniformly distributed within the dielectric material. The balanced topology thus allows for more uniform heating of the dielectric material along the column of material placed between the electrodes.

In various implementations this topology of the RF heating system 100 delivers the same heating power to the load as the unbalanced system of FIG. 5 while maintaining a lower voltage between the electrode plates in the applicator 108 and system ground. Because corona and arc discharge events require the potential to reach a high critical value, the lower potential difference between the electrodes and system ground reduces this discharge risk. The lowering of voltage between the electrodes has the added benefit of reducing the power absorbed by insulating materials placed between the electrodes and the supporting grounded structures in some applications.

Topology 3: Balanced Operation from Dual/Balanced RF Power Generator

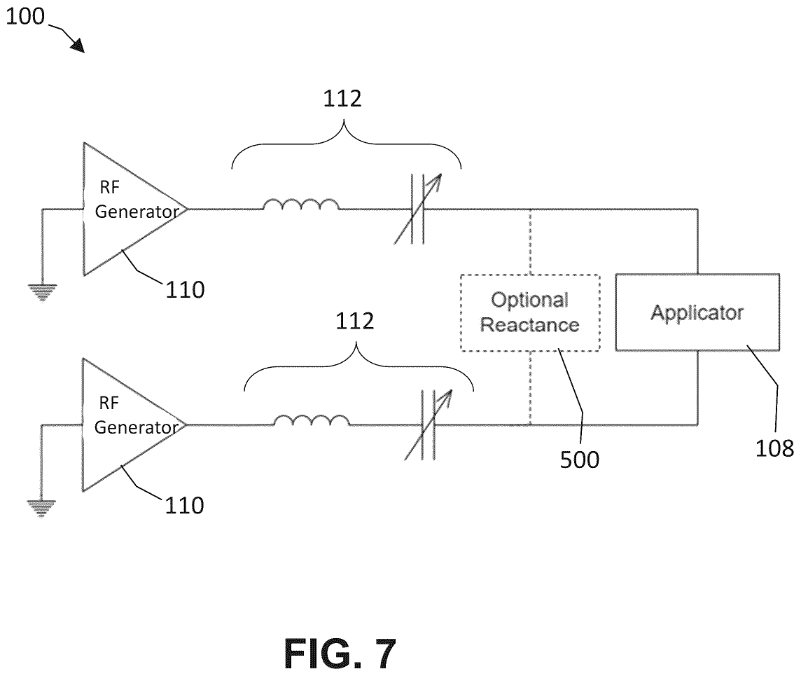

FIG. 7 is a high-level schematic that illustrates an example of the RF heating system 100 with an architecture using a balanced RF generator 110 on either end of the circuit. The two RF generators (sometimes considered parts of a single RF generator) are driven 180 degrees out of phase, with similar matching networks 112 on both applicator electrodes. This incorporates the advantages of the balanced architecture, while also requiring less combining than a single-ended system with a similar power and built using the same RF generator components.

### Control Methods

According to various implementations, one or more methods for achieving a constant output current from the RF power generator includes the use of control loops with current monitoring that regulates the output voltage of the RF power generator. Conceptual implementations of multiple control methods are described hereinafter. Several variations of these control methods are also possible.

### PWM Control

Some implementations of the technology use Pulse Width Modulation (PWM) to regulate the output voltage of the RF power generator. In various cases the system varies the duty cycle of the control signal so that voltage is switched to the load with a modified duty cycle that results in an average output voltage or power that approximates a desired level. In some cases, the system applies PWM to the supply voltage for the power amplifier(s) to modify and regulate the power generator's output voltage level. In various cases switching noise can be filtered with a reactive network.

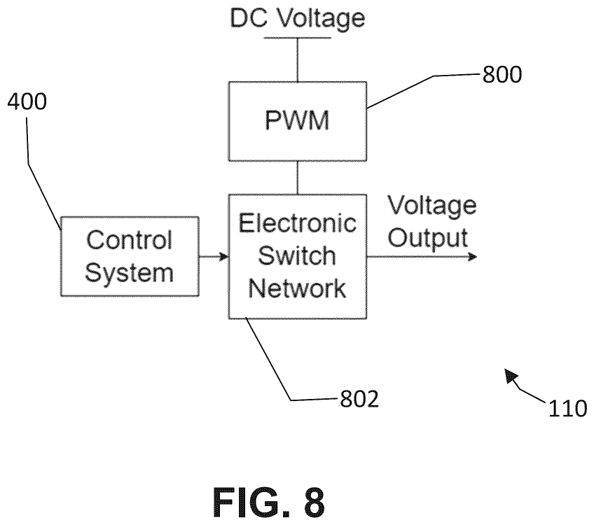

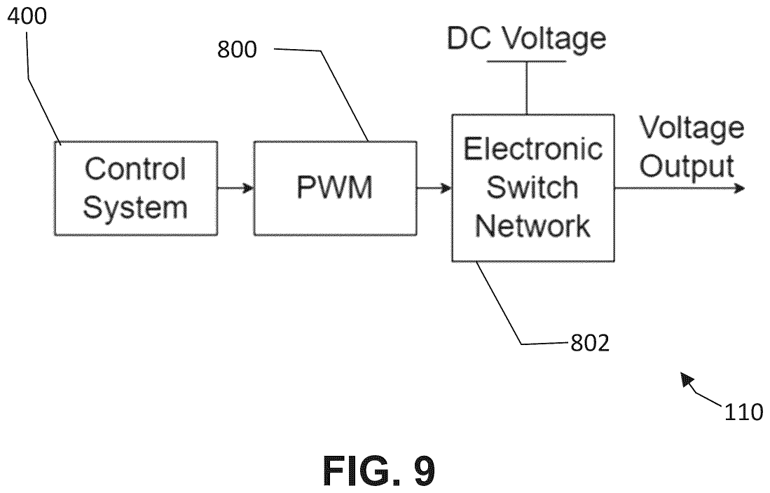

FIGS. 8 and 9 show two possible PWM control methods according to various implementations. FIG. 8 is a partial block diagram of an example RF power generator 110 in which PWM 800 is applied to the DC voltage supply that supplies one or more electronic switch networks 802 making up the power amplifier(s) 411 within the power amplifier stage 410. Applying pulse width modulation to the DC supply voltage provides one way to control the output voltage of the power amplifier stage. As an example, in various cases PWM 800 can be configured to step down or step up the supply voltage with, e.g., buck and boost voltage regulators, respectively. Those skilled in the art will appreciate that various other types of voltage regulation schemes can be used. FIG. 9 illustrates another way of controlling the output voltage with PWM 800 applied to the control signal generated by the control system 400. Varying the duty cycle of the control signal provides a way of regulating the output voltage of the power generator 110 by controlling the ON/OFF time of the gate drives of the amplifiers.

While FIGS. 8 and 9 depict two possible PWM control methods, it should be noted that the figures are high-level depictions and that the PWM control can be implemented in various manners. For example, in various cases the PWM control may be provided as part of the control system 400 or as separate circuitry.

### PCM Control

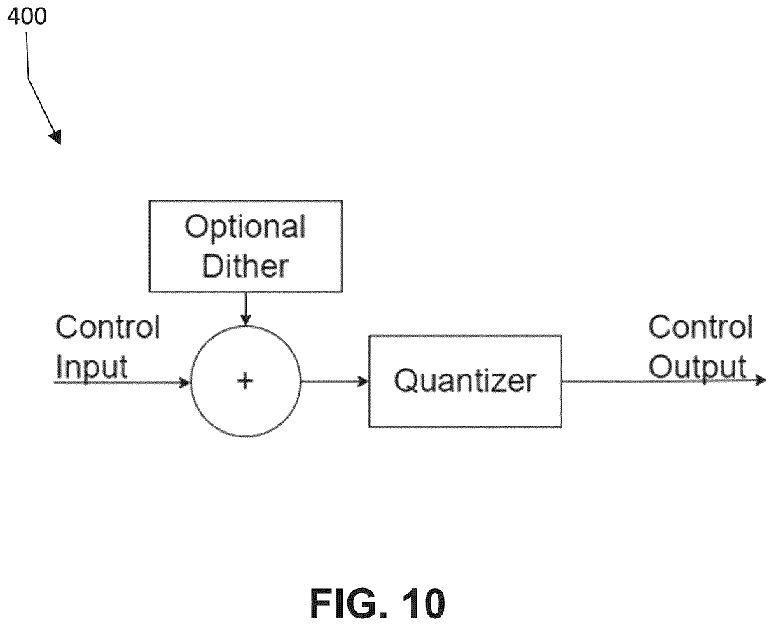

As shown in FIG. 10, Pulse Code Modulation (PCM) techniques for voltage regulation can be used in some implementations for constant current control of RF power generators. PCM control methods for output voltage regulation of the RF generators 110 involve sampling, quantizing, and encoding of control signals which are a derivative of the output current and voltage samples. These control signals are used for enabling or disabling individual amplifiers in the RF generator at any given time, thereby regulating the output voltage and resulting in constant current control. Individual amplifiers are enabled or disabled at a high rate to allow precise control of the output voltage.

### Sigma-Delta Control

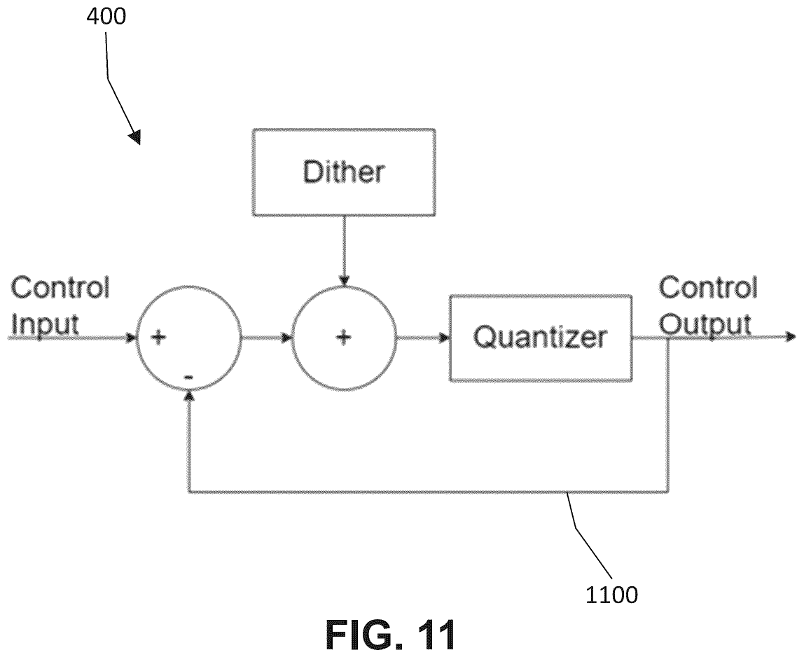

FIG. 11 illustrates an RF power generator control system 400 with an example of sigma-delta modulation according to various implementations. Sigma-delta modulation involves an oversampling technique that encodes signals into low bit depth digital signals at a much higher sampling frequency than the Nyquist frequency of the signal. To achieve higher quality output, the delta-sigma modulation employs a negative feedback loop 1100 during quantization to the lower bit depth, thereby continuously correcting quantization errors and shifting quantization noise to significantly higher frequencies than the original signal's bandwidth.

Various implementations use a sigma-delta control approach to determine the number of power amplifiers to be enabled at any given time, thereby regulating the RF power generator output voltage and providing constant current control. This approach provides the benefit of improved spectral purity and lower output ripple. While a simple first order embodiment of the sigma-delta modulator is shown in FIG. 11, this control method is extendable to higher order modulators.

In some cases, PCM techniques employed in the control of RF output power could result in quantization noise being injected into the signal chain. The effect of this noise could lead to undesirable artifacts anywhere along the AC input to RF output path. Dither, which is an intentionally applied form of noise, can be introduced to reduce tonal artifacts and improve the signal-to-noise characteristics of an RF heating system. In various cases, sigma-delta modulation provides the benefit of shaping the noise response such that the noise is pushed out of the frequency band of interest.

Although the disclosure has been described with reference to certain implementations and embodiments, persons skilled in the art will recognize that changes may be made in form and detail without departing from the spirit and scope of the disclosed apparatus, systems, and methods.

What is claimed is:

1. A Radio Frequency (RF) dielectric heating system, comprising:
a solid-state RF power generator comprising a power supply, an RF power amplifier stage electrically coupled to the power supply, and a control system electrically coupled to and configured to control the RF power amplifier stage;
a matching network electrically coupled to the RF power generator; and
a dielectric heating applicator electrically coupled to the matching network and comprising electrodes for applying RF power to a dielectric material;
wherein the control system is configured to regulate an output voltage of the RF power generator to provide a constant RF power generator output current to maintain a constant voltage across the applicator electrodes.

2. The RF dielectric heating system of claim 1, wherein the RF power amplifier stage comprises a single RF power amplifier.

3. The RF dielectric heating system of claim 1, wherein the RF power amplifier stage comprises a plurality of RF power amplifiers and wherein the RF power generator further comprises a combiner configured to combine outputs from the plurality of RF power amplifiers to produce an output RF signal.

4. The RF dielectric heating system of claim 1, wherein the control system is configured to regulate the output voltage of the RF power generator through pulse width modulation (PWM).

5. The RF dielectric heating system of claim 4, wherein the PWM comprises modulating a supply voltage of the amplifier stage.

6. The RF dielectric heating system of claim 4, wherein the control system is configured to generate an amplifier control signal to operate the RF power amplifier stage and wherein the PWM comprises regulating the output voltage of the RF power generator by modulating the amplifier control signal.

7. The RF dielectric heating system of claim 1, wherein the control system is configured to regulate the output voltage of the RF power generator through pulse code modulation (PCM).

8. The RF dielectric heating system of claim 1, wherein the control system is configured to regulate the output voltage of the RF power generator through sigma-delta modulation.

9. The RF dielectric heating system of claim 1, further comprising an unbalanced topology wherein the RF power generator is the only RF power generator.

10. The RF dielectric heating system of claim 1, further comprising a balanced topology wherein the RF power generator is the only RF power generator.

11. The RF dielectric heating system of claim 1, wherein the RF power generator is a first RF power generator and the matching network is a first matching network, and further comprising a second RF power generator and a second matching network electrically coupled between the second RF power generator and the dielectric heating applicator, wherein a control system of the second RF power generator is configured to drive the second RF power generator 180 degrees out of phase with the first RF power generator.

12. A solid-state radio frequency (RF) power generator for a dielectric heating system, the RF power generator comprising:
an RF generator output for electrically coupling to a matching network of a dielectric heating system;
an RF power amplifier stage electrically coupled to the RF generator output and comprising one or more RF power amplifiers;
a power supply electrically coupled to the RF power amplifier stage; and
a control system electrically coupled to the RF power amplifier stage;
wherein the control system is configured to regulate an output voltage at the RF generator output to provide a constant output current at the RF power generator output for driving a dielectric heating applicator of the dielectric heating system with a constant voltage.

13. The RF power generator of claim 12, further comprising a combiner electrically coupled between the RF power amplifier stage and the RF generator output, wherein the RF power amplifier stage comprises a plurality of RF power amplifiers and the combiner is configured to combine outputs from the plurality of RF power amplifiers to produce the output voltage at the RF generator output.

14. The RF power generator of claim 12, further comprising a pulse width modulation (PWM) circuit configured to regulate the output voltage.

15. The RF power generator of claim 14, wherein the PWM circuit is configured to regulate the output voltage by modulating a supply voltage generated by the power supply for the amplifier stage.

16. The RF power generator of claim 14, wherein the control system is configured to generate an amplifier control signal to operate the RF power amplifier stage and wherein the PWM circuit is configured to regulate the output voltage by modulating the amplifier control signal.

17. The RF power generator of claim 12, wherein the control system is configured to regulate the output voltage with pulse code modulation (PCM).

18. The RF power generator of claim 12, wherein the control system is configured to regulate the output voltage with sigma-delta modulation.

19. A method for heating a dielectric material with an RF dielectric heating system, comprising:
maintaining a constant voltage across electrodes of a dielectric heating applicator;
applying a constant current to a matching network electrically coupled to the dielectric heating applicator to generate the constant voltage; and
regulating an output voltage of an RF power generator to provide the constant current.

20. The method of claim 19, further comprising using pulse width modulation to regulate the output voltage.

21. The method of claim 19, further comprising using pulse code modulation to regulate the output voltage.

22. The method of claim 19, further comprising using sigma-delta modulation to regulate the output voltage.

23. The method of claim 19, further comprising maintaining the constant voltage with an unbalanced topology comprising a single RF power generator.

24. The method of claim 19, further comprising maintaining the constant voltage with a balanced topology comprising a single RF power generator.

25. The method of claim 19, further comprising maintaining the constant voltage with a balanced topology comprising a first RF power generator and a second RF power generator.

26. A method for heating a dielectric material with an RF dielectric heating system, comprising:
maintaining a constant voltage across electrodes of a dielectric heating applicator, optionally with a balanced or an unbalanced topology comprising one or more RF power generators;
applying a constant current to a matching network electrically coupled to the dielectric heating applicator to generate the constant voltage; and
regulating an output voltage of an RF power generator, optionally with one or more of pulse width modulation, pulse code modulation, and sigma-delta modulation, to provide the constant current.
